(19) United States
(12) Patent Application Publication
(10) Pub. No.: US 2005/0092246 A1
(43) Pub. Date: May 5, 2005

(54) Device for depositing thin layers with a wireless detection of process parameters

(76) Inventors: Peter Baumann, Aachen (DE); Gerd Strauch, Aachen (DE); Marcus Schumacher, Kerpen (DE); Walter Franken, Eschweiler (DE)

Correspondence Address: ST. ONGE STEWARD JOHNSTON & REENS, LLC, 986 BEDFORD STREET, STAMFORD, CT, 06905-5619, US

(21) Appl. No.: 10/922,660

(22) Filed: Aug. 20, 2004

Related U.S. Application Data
(63) Continuation of application No. PCT/EP03/01550, filed on Feb. 15, 2003.

(30) Foreign Application Priority Data
Feb. 22, 2002 (DE) 102 07 901.3

(51) Int. Cl. C23C 16/00

(52) U.S. Cl. 118/715; 118/712; 156/345.24

(57) ABSTRACT

The invention relates to a device for depositing thin, especially crystalline layers on at least one substrate, especially a crystalline substrate. Said device comprises a substrate holder which is rotationally arranged in a reactor housing and at least one sensor for measuring a process parameter and a transferring means for transferring the measured values of the process parameter to an evaluation device. The inventive transfer takes place in a wireless manner. The transmitter is arranged inside the reactor housing and a receiver is arranged outside the reactor housing.

This application is a continuation of pending International Patent Application No. PCT/EP2003/001550, filed Feb. 15, 2003, which designates the United States and claims priority of pending German Application No. 102 07 901.3, filed Feb. 22, 2002.

### FIELD OF THE INVENTION

The invention relates to a device for depositing thin, in particular crystalline layers on at least one, in particular crystalline substrate, having a substrate holder, which is mounted rotatably in a reactor housing, and having at least one sensor for measuring a process parameter and a transfer means for transferring the measured value to an evaluation device.

Devices for depositing thin films or layers are known, for example, from DE 199 40 033 A1, DE 199 19 902 A1, WO00/165592A2, WO00/155,478A2. These documents describe in particular devices in which the substrate holder is driven in rotation.

The prior art has disclosed CVD installations in which the process parameters, such as the temperature of the substrate or the gas pressure inside the process chamber, are measured in order to control the process conditions. These measured values are transferred to an evaluation device, for example an electronic control device, by means of transfer means, in the form of electrical lines or optical lines. Therefore, process conditions are only recorded and monitored indirectly and not in the vicinity of the immediate location. The measured values may deviate from the values which actually exist in situ. Moreover, the measured values are determined in a fixed position with respect to the process chamber reference system but not in a fixed position with respect to the rotating substrate holder reference system. The quality of the layers which are deposited on the substrates, which are located on substrate holders driven in rotation, is critically dependent on a large number of process conditions. These have to be determined and monitored accurately and reproducibly. The local distribution of the process conditions within the CVD reactor and in particular at the rotating substrate holder is particularly important in this context. The more accurately and reproducibly it is possible to determine such process conditions, the better the monitoring of the quality of the deposited layers.

The invention is based on the object of providing means which improve the recording of the process parameters.

The object is achieved by the invention given in the claims. Claim 1 provides firstly and substantially for the transfer means to have a transmitter and a receiver for wireless transmission of the measured value. The sensor is preferably located inside the reactor housing, and the receiver is preferably located outside the reactor housing. It is advantageous if the sensor is associated with a drive shaft for the substrate holder. It is particularly advantageous if the sensor rotates with the substrate holder and the receiver is disposed in a fixed position. The receiver may, for example, be formed as a ring antenna and may surround the drive shaft for the substrate holder or the shaft passage in which the drive shaft runs. A suitable sensor is in particular a thermocouple which is located in the substrate holder. The leads to the thermocouple may be routed through the drive shaft to the transmitter. This transmitter may simultaneously have an evaluation circuit for evaluating the electrical signal emitted by the thermocouple. This signal is processed in suitable form and transmitted to the receiver by means of the transmitter. It is particularly advantageous if the transmitter transfers the measured values from a multiplicity of sensors to the receiver. The multiplicity of sensors may comprise a multiplicity of thermocouples. However, it is also possible to provide a plurality of pressure sensors. In this case too, it is advantageous if the pressure pick-ups are disposed at a location close to the transmitter. Pressure pick-ups or sensors are located in a region of the interior of the reactor housing which is purged with inert gas. The pressure pick-ups may be connected by means of capillaries to the locations at which the pressures are to be recorded. These capillaries may, for example, be formed by thin special steel tubes. The sensors, i.e. the thermocouples or the ends of the capillaries can be disposed at various locations of the substrate holder. For example, the sensors may be disposed in various radial positions in the substrate holder. However, they may also be disposed at various circumferential positions there. The thermocouples may be disposed close to the surface and may be seated immediately beneath the substrate, in order to measure the temperature of the back surface of the substrate. However, the thermocouples may also be disposed within the bulk of the substrate holder, which consists of graphite, in order to measure the temperature there.

According to the invention, the measured values are communicated by telemetry from a measured value pick-up to an evaluation unit. There is in particular a multiplicity of identical or different sensors, the measured values from which are communicated wirelessly to a data processing location. The direct temperature measurement eliminates the drawbacks of optical temperature measurement, which is dependent on the surface emissivity. On account of the fact that capillaries are accommodated at various locations in the substrate holder, it is possible to determine the pressure distribution above the substrate holder in the process chamber. It is possible to determine the pressure at the edge of the substrate directly, specifically at various circumferential positions of the substrate. In this way, it is also possible to determine the flow distribution within the process chamber. The substrate holder is in the form of a circular disk. The gas is supplied in the center above the substrate holder, so that the gas supplied is displaced radially outward. This gas flow is influenced by the pressure conditions.

### BRIEF DESCRIPTION OF THE DRAWINGS

Exemplary embodiments of the invention are explained below with reference to accompanying drawings, in which:

FIG. 1 shows a highly diagrammatic illustration of the lower part of a reaction housing with a rotationally driven substrate holder and substrate resting thereon;

FIG. 2 shows a plan view of a second exemplary embodiment of the invention;

FIG. 3 shows a section on line III-III in FIG. 2;

FIG. 4 shows a third exemplary embodiment of the invention in the form of a plan view as shown in FIG. 2; and

FIG. 5 shows a section on line V-V in FIG. 4.

### DETAILED DESCRIPTION OF DRAWINGS

The reactor housing 2 is only illustrated quite diagrammatically and partially in FIG. 1. This is a MOCVD reactor with a central gas supply, which is not shown in the drawings and is located directly above the substrate 1. Reactor housings of the type under discussion are described in particular by DE 199 40 033 A1, DE 199 19 902 A1, WO00/165,592A2, WO00/155,478A2 and WO00/146,498A2.

The substrate 1 is positioned on a substrate holder 3, which is in the form of a circular disk and is made from graphite. Beneath the substrate holder 3 there is a radiofrequency heating means 12, by which the substrate holder 3 can be brought to the process temperature. The substrate holder 3 is driven in rotation during the coating process. This is done by a drive shaft 8, which is hollow in form and runs within a shaft passage 9. The drive shaft 8 is mounted rotatably in the shaft passage 9 by means of rotary bearings 10 and 11.

Reference numerals 4 and 5 denote sensors which are located inside the substrate holder 3 and accordingly rotate therewith. Lines 14, 15 lead to the sensors 4, 5. These lines 14, 15 connect the sensors 4, 5 to a transmitter 6, which also comprises a measured value processing circuit.

The values measured by the sensors 4, 5 are transferred to the processing circuit by means of the lines 14, 15. The transmitter 6 communicates the measured values to a ring antenna 7 surrounding the drive shaft 8 and the shaft passage 9. The receiver, which is formed by the ring antenna 7, transmits these measured values to an evaluation device (not shown).

In the exemplary embodiment illustrated in FIGS. 2 and 3, the sensors 4 are temperature sensors in each case in the form of thermocouples 4, 4′. The electric feed lines 15 for the thermocouples 4, 4′ run through passages 13 in the substrate holder 3 and through the hollow drive shaft 8 to the transmitter 6. There, the voltages on the electric lines are measured and are converted into temperature values which are suitable for transmission and are then transmitted to the receiver 7 by the transmitter 6.

Two types of thermocouples 4, 4′ are provided in the exemplary embodiment shown in FIGS. 2 and 3. The thermocouples denoted by reference numeral 4 are located in a passage 13 one after the other in the radial direction, in different radial positions approximately in the center of the cross section of the substrate holder 3. The sensors denoted by 4′ are circumferentially distributed, for example in each case offset by 120°, at a different radial distance from the center of the substrate holder 3 immediately beneath the substrate 1. The temperature of the substrate back surface can therefore be measured by these thermocouples 4′.

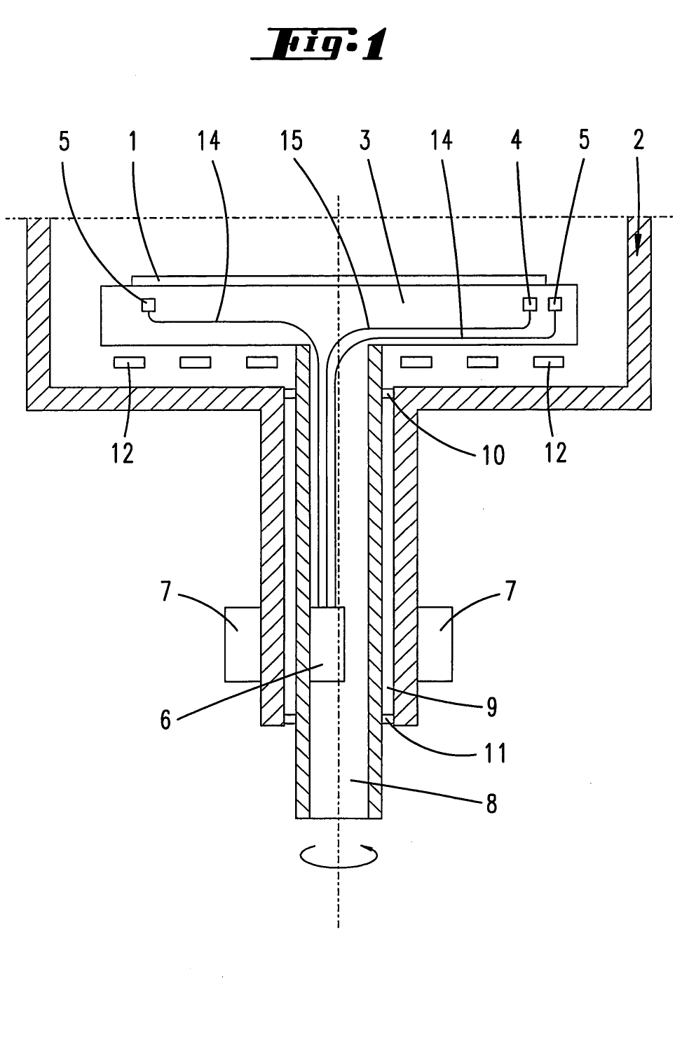

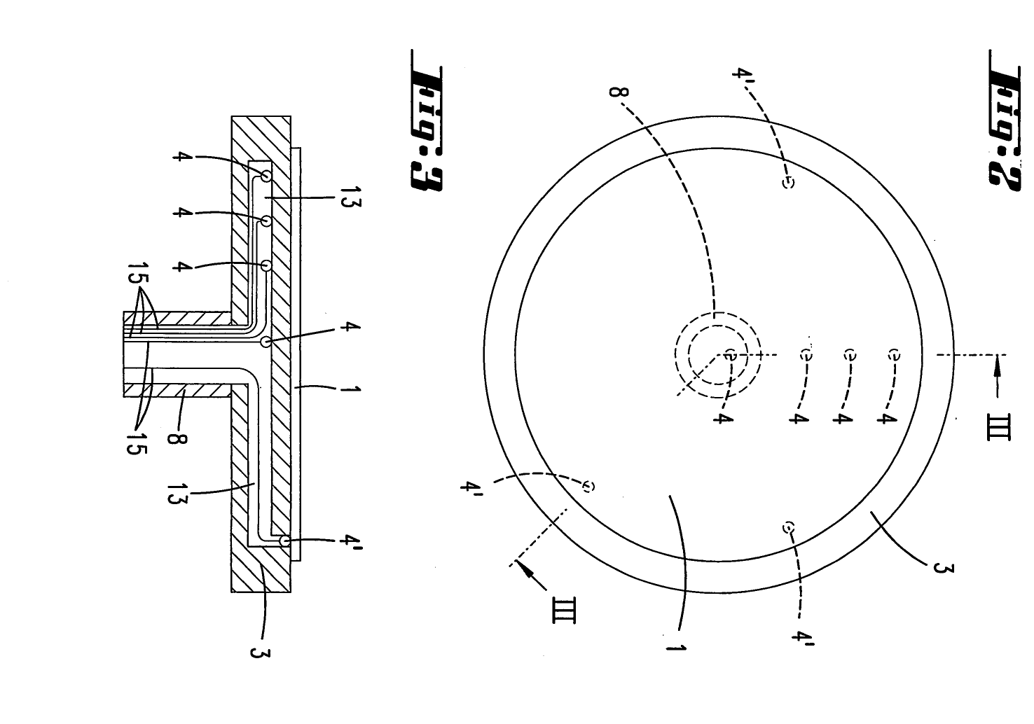

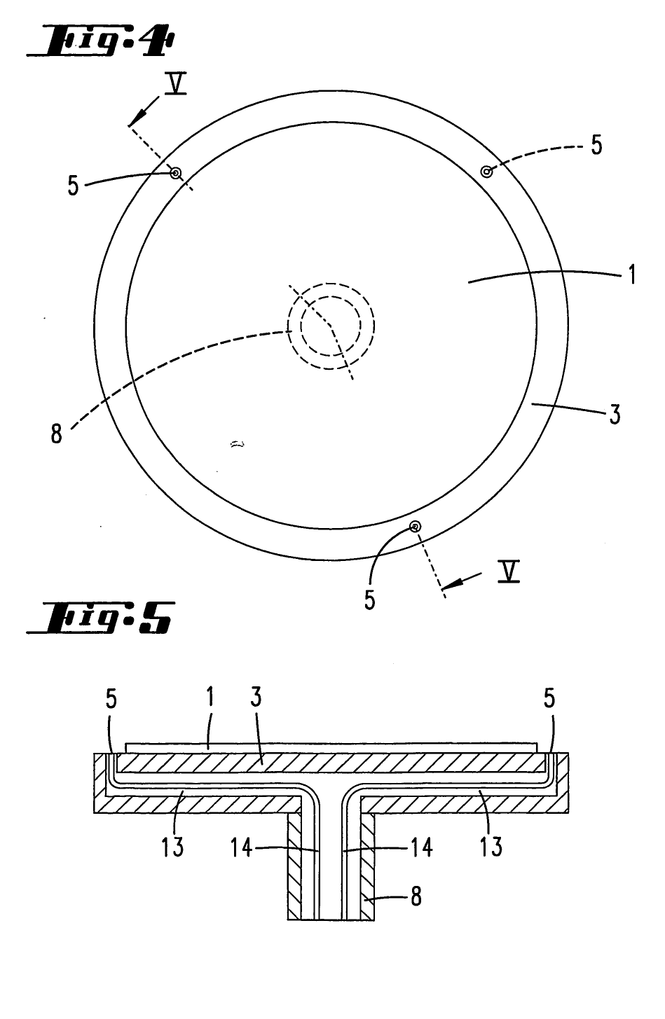

In the exemplary embodiment illustrated in FIGS. 4 and 5, the sensors are pressure sensors 5. These pressure sensors 5 are formed by the ends of capillaries. These capillaries are formed by thin special steel small-bore tubes (eighth-of-an-inch tubes). These tubes 14 likewise run through passages 13 in the substrate holder and through the cavity in the drive shaft 8 to a pressure pick-up which is associated with the transmitter 6. There, the pressure prevailing above the opening of the small-bore tube in the gas phase is measured. The gas pressure value is converted into an electrical value, is transmitted by the transmitter 6 and received by the antenna 7.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

1. Device for depositing thin, in particular crystalline layers on at least one, in particular crystalline substrate, having a substrate holder, which is disposed rotatably in a reactor housing, and having at least one sensor for measuring a process parameter and a transfer means for transferring the measured value for the process parameter to an evaluation device, characterized in that the transfer means includes a transmitter and a receiver for wireless communication of the measured value, the transmitter being associated with a drive shaft for the substrate holder, and the receiver being disposed outside the reactor housing and in particular being a ring antenna which surrounds the drive shaft or a shaft passage which accommodates the drive shaft.

2. Device according to claim 1, characterized in that the at least one sensor is a thermocouple.

3. Device according to claim 1, characterized in that the at least one sensor is a pressure pick-up.

4. Device according to claim 1, characterized by a multiplicity of thermocouples or pressure pick-ups.

5. Device according to claim 1, characterized in that the sensors are disposed at various radial positions in the substrate holder.

6. Device according to claim 1, characterized in that the sensors are disposed at various circumferential positions in the substrate holder.

7. Device according to claim 1, characterized in that the leads to the sensors are routed through passages in the substrate holder.

8. Device according to claim 1, characterized in that the pressure-measuring device or the thermocouple evaluation circuit is locally associated with the transmitter.

9. Device according to claim 1, characterized by tubes leading from the transmitter to the measurement locations.
